(19) United States
(12) Patent Application Publication
(10) Pub. No.: US 2022/0163428 A1
(43) Pub. Date: May 26, 2022

(54) DAMPER CONDITION MONITORING FOR A DAMPER OF A GAS TURBINE ENGINE

(71) Applicant: General Electric Company, Schenectady, NY (US)

(72) Inventors: Kanahayya Dudhale, Bangalore (IN); Peeyush Pankaj, Bangalore (IN); Praveen Sharma, Bangalore (IN)

(21) Appl. No.: 17/101,446

(22) Filed: Nov. 23, 2020

(51) Int. Cl. G01M 15/14; G01M 13/045; G06F 30/17

(52) U.S. Cl. CPC G01M 15/14; G06F 30/17; G01M 13/045

(57) ABSTRACT

Systems, methods, and a gas turbine engine that includes features for condition monitoring of a damper thereof are provided. In one aspect, a gas turbine engine includes a rotary component, a bearing operatively coupled with the rotary component, and a damper associated with the bearing. The gas turbine engine also includes sensors and a controller. The controller receives data that includes sensed and/or calculated parameter values. The controller generates a damper severity index based on the parameter values. The damper severity index indicates a health state of the damper. The controller determines whether the damper severity index exceeds a threshold. When the damper severity index exceeds the threshold, a notification indicating the health state of the damper is generated. A computing system can determine a fault type and a remaining useful life of the damper and can update controller logic based on field data received from engines in a fleet.

### FIELD

The present subject matter relates generally to damper condition monitoring for a damper of a turbomachine, such as a gas turbine engine.

### BACKGROUND

Rotary components of turbomachines can experience a wide range of vibrational loads during operation. For instance, a rotor of an aviation gas turbine engine can experience a large range of vibrational amplitudes and eccentricities depending on the operational conditions of the engine. Typically, one or more bearings support one or more shafts of the rotor. The shafts are typically supported and retained by the bearings and vibrational loads are controlled and dampened by dampers, such as squeeze film dampers. In some instances, such dampers can fail or otherwise become ineffective. Presently, there is no satisfactory method for monitoring the condition or health state of such dampers.

Therefore, systems and methods of damper condition monitoring that address one or more of the challenges noted above would be useful.

### BRIEF DESCRIPTION

Aspects and advantages of the invention will be set forth in part in the following description, or may be obvious from the description, or may be learned through practice of the invention.

In one aspect, a gas turbine engine is provided. The gas turbine engine includes a rotary component rotatable about an axis of rotation, a bearing operatively coupled with the rotary component, and a damper associated with the bearing. Further, the gas turbine engine includes one or more sensors and a controller communicatively coupled with the one or more sensors. The controller has one or more processors and one or more memory devices. The one or more processors of the controller are configured to: receive data from the one or more sensors; generate a damper severity index based at least in part on the data received from the one or more sensors, the damper severity index indicating a health state of the damper; determine whether the damper severity index exceeds a threshold; and generate, when the damper severity index exceeds the threshold, a notification indicating the health state of the damper.

In another aspect, a method is provided. The method includes receiving, by a controller of a gas turbine engine, data from one or more sensors associated with the gas turbine engine. Further, the method includes generating, by the controller, a damper severity index based at least in part on the data received from the one or more sensors, the damper severity index indicating a health state of a damper associated with a bearing operatively coupled with a rotary component of the gas turbine engine. In addition, the method includes determining, by the controller, whether the damper severity index exceeds a threshold. Further, the method includes generating, by the controller, a notification indicating the damper severity index exceeds the threshold.

In a further aspect, a non-transitory computer readable medium is provided. The non-transitory computer readable medium comprises computer-executable instructions, which, when executed by one or more processors, cause the one or more processors to: access field data received from one or more gas turbine engines of a fleet, the field data received from a given one of the one or more gas turbine engines including parameter values for parameters associated with the given one of the one or more gas turbine engines, each of the one or more gas turbine engines including a damper; access a machine-learned model trained using one or more condition indicators identified from the field data, the one or more condition indicators each indicating a feature identified from the field data related to degradation of at least one of the dampers; receive a second set of field data that includes parameter values for parameters associated with a gas turbine engine having a damper; and generate, using the second set of field data as an input to the machine-learned model, an output indicating a remaining useful life of the damper of the gas turbine engine.

In another aspect, a method of training a machine-learned model is provided. The method includes receiving, by one or more computing devices, field data from one or more gas turbine engines of a fleet, the field data received from a given one of the one or more gas turbine engines including parameter values for parameters associated with the given one of the one or more gas turbine engines, each of the one or more gas turbine engines including a damper. Further, the method includes identifying, by the one or more computing devices, one or more condition indicators from the field data that each indicate a parameter that affects degradation of a damper associated with the one or more gas turbine engines of the fleet. In addition, the method includes training, by the one or more computing devices, the machine-learned model using the one or more condition indicators identified in the field data, the trained machine-learned model being configured to generate an output indicating a health state of a damper of a gas turbine engine upon a second set of data being input therein, the second set of field data including parameter values for parameters associated with a gas turbine engine having a damper.

In yet another aspect, a computing system is provided. The computing system includes one or more memory devices and one or more processors. The one or more processors are configured to: receive, from one or more gas turbine engines of a fleet, field data, the field data received from a given one of the one or more gas turbine engines including parameter values for parameters associated with the given one of the one or more gas turbine engines, each of the one or more gas turbine engines including a damper; identify one or more condition indicators from the field data, the one or more condition indicators each indicating a feature identified from the field data that affects degradation of at least one of the dampers; train a machine-learned model using the one or more condition indicators; receive, from a gas turbine engine of the fleet, a second set of field data including parameter values for parameters associated with the gas turbine engine; and generate, using the second set of field data as an input to the machine-learned model, an output indicating a remaining useful life of the damper of the gas turbine engine.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 provides a schematic cross-sectional view of an exemplary gas turbine engine according to various embodiments of the present disclosure;

FIG. 2 provides a close-up schematic view of one of the bearings of the gas turbine engine of FIG. 1;

FIG. 3 provides a block diagram of a damper condition monitoring system according to an example embodiment of the present disclosure;

FIG. 4 provides a graph depicting generated damper severity indices plotted as a function of time according to an example embodiment of the present disclosure;

FIG. 5 provides a block diagram of a computing system of the damper condition monitoring system of FIG. 3;

FIG. 6 provides a graph depicting the amplitude of a healthy signal for a parameter as a function of frequency during healthy operation of the damper and also depicts the amplitude of a faulty operation signal for the parameter as a function of frequency during faulty operation of the damper;

FIG. 7 provides a simplified flow diagram of a first machine-learned model according to an example embodiment of the present disclosure;

FIG. 8 provides a simplified flow diagram of a second machine-learned model according to an example embodiment of the present disclosure;

FIG. 9 provides a simplified flow diagram of a third machine-learned model according to an example embodiment of the present disclosure;

FIG. 10 provides a simplified flow diagram of a fourth machine-learned model according to an example embodiment of the present disclosure; and

FIG. 11 provides a flow diagram for a method of monitoring a health state of a damper of a gas turbine engine according to an example embodiment of the present disclosure.

### DETAILED DESCRIPTION

Reference will now be made in detail to present embodiments of the invention, one or more examples of which are illustrated in the accompanying drawings. Each example is provided by way of explanation of the invention, not limitation of the invention. In fact, it will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention covers such modifications and variations as come within the scope of any claims and their equivalents.

The detailed description uses numerical and letter designations to refer to features in the drawings. Like or similar designations in the drawings and description have been used to refer to like or similar parts of the invention, and identical numerals indicate the same elements throughout the drawings. As used herein, the terms “first”, “second”, and “third” may be used interchangeably to distinguish one component from another and are not intended to signify location or relative importance of the individual components. The terms “upstream” and “downstream” refer to the relative direction with respect to fluid flow in a fluid pathway. For example, “upstream” refers to the direction from which the fluid flows, and “downstream” refers to the direction to which the fluid flows.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 1, 2, 4, 5, 10, 15, or 20 percent margin in either individual values, range(s) of values, and/or endpoints defining range(s) of values.

Aspects of the present disclosure are directed to damper condition monitoring of a damper of a turbomachine, such as a gas turbine engine. In one aspect, a gas turbine engine is provided that includes features for monitoring a condition or health state of a damper thereof. The gas turbine engine can be an aviation gas turbine engine mounted to an aircraft, for example. The gas turbine engine includes a rotary component rotatable about an axis of rotation. For instance, the rotary component can be a low pressure or high pressure shaft of the gas turbine engine. A bearing is operatively coupled with the rotary component to provide support thereto. A damper associated with the bearing is provided to dampen vibrations of the rotary component. The gas turbine engine can also include one or more sensors and a controller communicatively coupled with the one or more sensors. The controller has one or more processors and one or more memory devices, such as one or more non-transitory memory devices.

The one or more processors of the controller are configured to receive data from the one or more sensors. In some embodiments, vehicle data can be received as well. The one or more processors of the controller are configured generate a damper severity index based at least in part on the received data. The damper severity index indicates a health state of the damper. The damper severity index can be generated based on a plurality of parameter values that are derived from the data; accordingly, the parameter values can be sensed or calculated values. Weights can be applied to the parameter values such that the parameter values are weighed parameter values. The weighted parameter values can be used to generate a weighted average or any other statistical combination of the weighted parameter values, rendering the damper severity index. In some embodiments, a statistical or machine-learned model can generate the damper severity index. The one or more processors of the controller are further configured to determine whether the damper severity index exceeds a threshold, and when the damper severity index exceeds the threshold, a notification indicating the health state of the damper can be generated. In some embodiments, the severity of the health state of the damper can be determined and included in the notification. The notification can be provided to one or more entities, such as an engine service entity. Based on the notification, the engine service entity can schedule a service visit for the gas turbine engine.

In another aspect, a computing system of a condition monitoring system is provided. Generally, the computing system receives field data from gas turbine engines of a fleet, uses the received field data to identify condition indicators that indicate a feature identified from the field data that affects degradation of a damper associated with the engines of the fleet. One or more models can be trained and/or retrained using the received field data and the identified condition indicators, rendering one or more machine-learned models. One of the machine-learned models can generate, using the new field data as an input to the machine-learned model, an output indicating a remaining useful life of the damper of the gas turbine engine. One of the machine-learned models can generate, using the new field data as an input to the machine-learned model, an output indicating a fault type of the damper of the gas turbine engine. One of the machine-learned models can generate, using the new field data as an input to the machine-learned model, an output indicating an anomaly in the field data.

In some embodiments, the computing system, using a machine-learned model such as a classification machine-learned model, can identify parameters that impact or affect damper health. The degree in which each parameter affects degradation of a damper can be determined. The machine-learned model can classify and rank the parameters by degree of impact to the degradation of the damper. Accordingly, update data can be generated by the computing system. The update data can include updated weights to be applied to parameters during the generation of the damper severity index. In this way, the computing system can generate and provide a self-evolving damper Prognostic Health Management (PHM) logic to the controller of the engine. In this manner, the accuracy of the damper severity indices generated by the controller can become more accurate over time, which improves the overall monitoring of the damper or dampers of a gas turbine engine. The update data can be provided to all engines in a fleet. The update data can be provided to an engine of the fleet while the engine is on the ground or visiting a Maintenance, Repair, and Overhaul (MRO) shop, for example. A method of monitoring a condition or health state of a damper of a gas turbine engine is also provided.

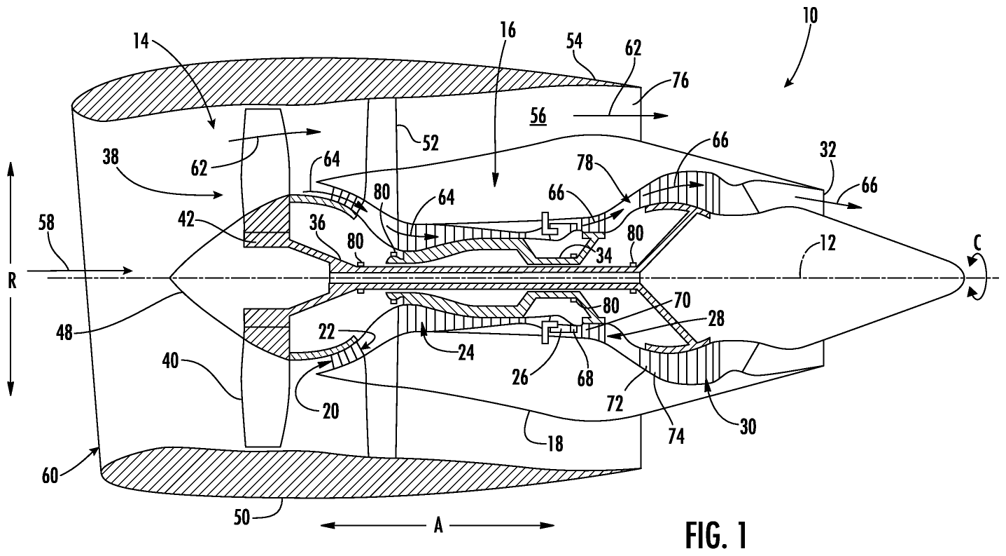

Referring now to the drawings, FIG. 1 provides a schematic cross-sectional view of a turbomachine embodied as a gas turbine engine for an aerial vehicle. For the embodiment of FIG. 1, the gas turbine engine is a high-bypass turbofan jet engine 10, referred to herein as “turbofan 10.” The turbofan 10 defines an axial direction A (extending parallel to a longitudinal centerline 12) and a radial direction R that is normal to the axial direction A. The turbofan 10 also defines a circumferential direction C that extends three hundred sixty degrees (360°) around the longitudinal centerline 12.

The turbofan 10 includes a fan section 14 and a core turbine engine 16 disposed downstream of the fan section 14. The core turbine engine 16 includes a substantially tubular outer casing 18 that defines an annular core inlet 20. As schematically shown in FIG. 1, the outer casing 18 encases, in serial flow relationship, a compressor section including a booster or low pressure (LP) compressor 22 followed downstream by a high pressure (HP) compressor 24; a combustion section 26; a turbine section including an HP turbine 28 followed downstream by an LP turbine 30; and a jet exhaust nozzle section 32. The compressor section, combustion section 26, turbine section, and nozzle section 32 together define a core air flowpath. An HP shaft or spool 34 drivingly connects the HP turbine 28 to the HP compressor 24 to rotate them in unison concentrically with respect to the longitudinal centerline 12. An LP shaft or spool 36 drivingly connects the LP turbine 30 to the LP compressor 22 to rotate them in unison concentrically with respect to the longitudinal centerline 12. Thus, the LP shaft 36 and HP shaft 34 are each rotary components, rotating about the axial direction A during operation of the turbofan 10.

In order to support such rotary components, the turbofan 10 includes a plurality of bearings 80 attached to various static structural components within the turbofan 10. Specifically, for the embodiment depicted in FIG. 1, the bearings 80 support and facilitate rotation of, e.g., the LP shaft 36 and the HP shaft 34. Further, as will be described herein, the bearings 80 can include or be associated with one or more dampers operable to dampen vibrational energy imparted to bearings 80 during operation of the turbofan 10. Although the bearings 80 are described and illustrated as being located generally at forward and aft ends of the respective LP shaft 36 and HP shaft 34, the bearings 80 may additionally, or alternatively, be located at any desired location along the LP shaft 36 and HP shaft 34 including, but not limited to, central or mid-span regions of the shafts 34, 36, or other locations along shafts 34, 36.

The fan section 14 includes a fan 38 having a plurality of fan blades 40 coupled to a disk 42 in a spaced apart manner. The fan blades 40 extend outward from the disk 42 along the radial direction R. The fan blades 40 and the disk 42 are together rotatable about the longitudinal axis 12. The disk 42 is covered by a rotatable spinner 48 aerodynamically contoured to promote an airflow through the plurality of fan blades 40. In addition, the fan section 14 includes an annular fan casing or outer nacelle 50 that circumferentially surrounds the fan 38 and/or at least a portion of the core turbine engine 16. The nacelle 50 is supported relative to the core turbine engine 16 by a plurality of circumferentially-spaced outlet guide vanes 52. Alternatively, the nacelle 50 also may be supported by struts of a structural fan frame. Moreover, a downstream section 54 of the nacelle 50 may extend over an outer portion of the core turbine engine 16 so as to define a bypass airflow passage 56 therebetween.

During operation of the turbofan 10, a volume of air 58 enters the turbofan 10 through an associated inlet 60 of the nacelle 50 and/or fan section 14. As the volume of air 58 passes across the fan blades 40, a first portion of the air 58 as indicated by arrow 62 is directed or routed into the bypass airflow passage 56, and a second portion of the air 58 as indicated by arrow 64 is directed or routed into the upstream section of the core air flowpath, or more specifically into the annular core inlet 20 of the LP compressor 22. The pressure of the second portion of air 64 is then increased as it is routed through the high pressure (HP) compressor 24. The high pressure air 64 is then discharged into the combustion section 26 where the air 64 is mixed with fuel and burned to provide combustion gases 66.

The combustion gases 66 are routed into and expand through the HP turbine 28 where a portion of thermal and/or kinetic energy from the combustion gases 66 is extracted via sequential stages of HP turbine stator vanes 68 that are coupled to the outer casing 18 and HP turbine rotor blades 70 that are coupled to the HP shaft or spool 34, thus causing the HP shaft or spool 34 to rotate, thereby supporting operation of the HP compressor 24. The combustion gases 66 then flow downstream into and expand through the LP turbine 30 where a second portion of thermal and kinetic energy is extracted from the combustion gases 66 via sequential stages of LP turbine stator vanes 72 that are coupled to the outer casing 18 and LP turbine rotor blades 74 that are coupled to the LP shaft or spool 36, thus causing the LP shaft or spool 36 to rotate, thereby supporting operation of the LP compressor 22 and rotation of the fan 38.

The combustion gases 66 are subsequently routed through the jet exhaust nozzle section 32 of the core turbine engine 16 to provide propulsive thrust. Simultaneously, the pressure of the first portion of air 62 is substantially increased as the first portion of air 62 is routed through the bypass airflow passage 56 before it is exhausted from a fan nozzle exhaust section 76 of the turbofan 10, also providing propulsive thrust. The HP turbine 28, the LP turbine 30, and the jet exhaust nozzle section 32 at least partially define a hot gas path 78 for routing the combustion gases 66 through the core turbine engine 16.

It should be appreciated that the exemplary turbofan 10 depicted in FIG. 1 is by way of example only, and that in other exemplary embodiments, the turbofan 10 may have any other suitable configuration. For example, in other exemplary embodiments, the fan 38 may be configured in any other suitable manner (e.g., as a variable pitch fan) and further may be supported using any other suitable fan frame configuration. Moreover, it also should be appreciated that in other exemplary embodiments that any other suitable HP compressor 24 and HP turbine 28 configurations may be utilized. It also should be appreciated, that in still other exemplary embodiments, aspects of the present disclosure may be incorporated into any other suitable gas turbine engine. For example, aspects of the present disclosure may be incorporated into, e.g., a turboshaft engine, turboprop engine, turbojet engine, etc. Further, in still other embodiments, aspects of the present disclosure may be incorporated into any other suitable turbomachine, including, without limitation, a steam turbine, a centrifugal compressor, and/or a turbocharger.

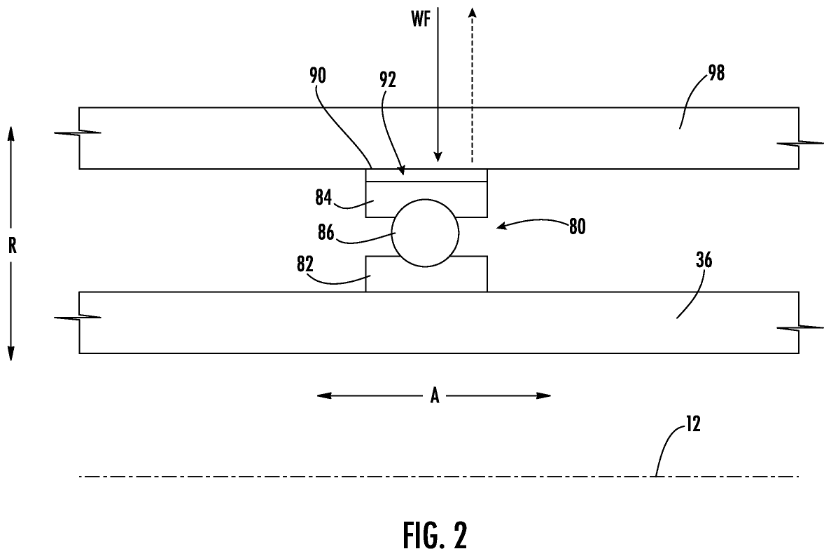

FIG. 2 provides a close-up schematic view of one of the bearings 80 of the turbofan 10 of FIG. 1. As depicted in FIG. 2, the bearing 80 is operatively coupled with a rotary component rotatable about an axis of rotation. For this embodiment, the rotary component is the LP shaft 36 and the axis of rotation is the longitudinal centerline 12. The LP shaft 36 is supported by the bearing 80 operatively coupled thereto.

The bearing 80 includes an inner race 82 connected to the LP shaft 36, an outer race 84 connected to a static structure or stationary component 98 of the turbofan 10 (FIG. 1), and bearing elements 86 positioned therebetween (only one shown in FIG. 2). The inner race 82 is positioned inward of the outer race 84 along the radial direction R with respect to the longitudinal centerline 12. The bearing elements 86 can be spherical balls or other suitable bearing elements, for example.

Notably, the bearing 80 has an associated damper 90 defining a chamber 92. For this embodiment, the damper 90 is a squeeze film damper. In some embodiments, the damper 90 can be integrally formed with the outer race 84 or some other structure of the bearing 80. In other embodiments, the damper 90 can be a separate component from the bearing 80 and can be connected to the outer race 84 or some other structure of the bearing 80. For the depicted embodiment of FIG. 2, the damper 90 is integrally formed with the outer race 84. A working fluid WF (e.g., oil) can be directed into the chamber 92 of the damper 90 associated with the bearing 80. The damping response or stiffness provided by the damper 90 can be varied by controlling the volume of working fluid WF directed to and/or drained from the chamber 92. In this way, the damping response of the damper 90 can be controlled by varying the volumetric flow rate of the working fluid WF flowing to or from the chamber 92. Additionally or alternatively, the damping response provided by the damper 90 can be controlled by varying the pressure and/or temperature of the working fluid WF. In this manner, the damper 90 can dampen vibrational loads and provide rotor stability to the shaft 36 and components connected thereto for a wide range of operating conditions.

It will be appreciated that other bearings 80 of the turbofan 10 of FIG. 1 can likewise have associated dampers. For instance, each bearing 80 operatively coupled with the LP shaft 36 can have an associated damper. Further, each bearing 80 operatively coupled with the HP shaft 34 can have an associated damper. In addition, other bearings of the turbofan 10 can each have an associated damper. The dampers associated with their respective bearings can be squeeze film dampers, for example. The dampers can be integral with or connected to their respective bearings. The dampers can be arranged in the same or similar manner as the damper 90 is arranged with respect to the bearing 80 depicted in FIG. 2.

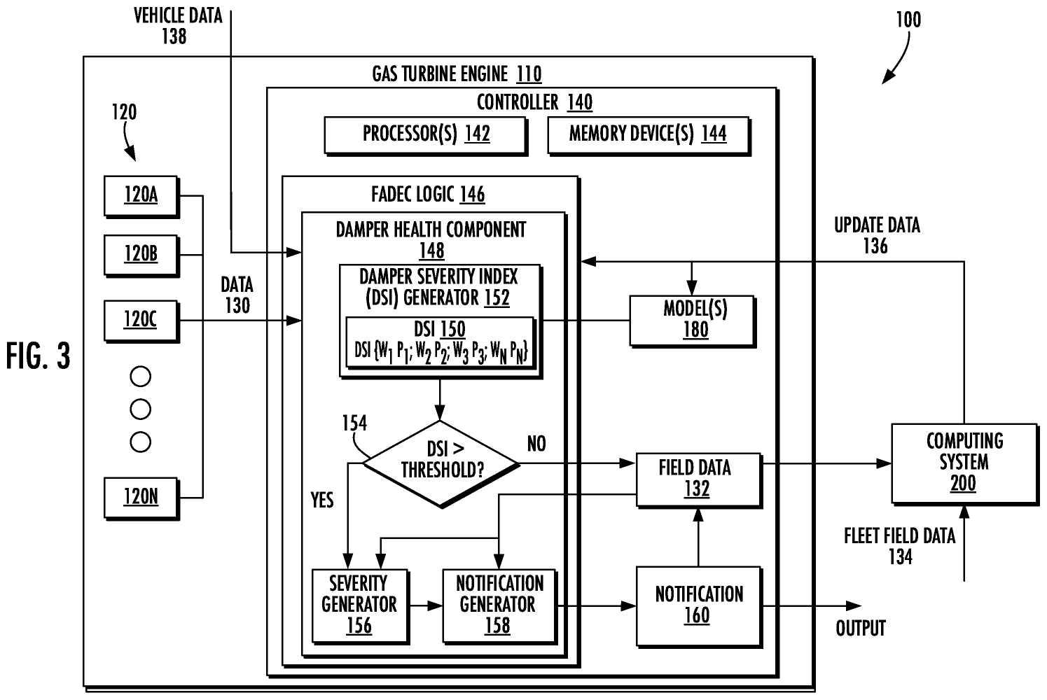

FIG. 3 provides a block diagram of a damper condition monitoring system 100 according to an example embodiment of the present disclosure. Generally, the damper condition monitoring system 100 can be used to monitor a condition or health state of a damper. For instance, the damper condition monitoring system 100 can be used to monitor the condition or health state of the damper 90 associated with the bearing 80 of FIG. 2.

As shown in FIG. 3, the system 100 includes a turbomachine, which in this embodiment is a gas turbine engine 110. The gas turbine engine 110 can be the turbofan 10 of FIG. 1, for example. The gas turbine engine 110 includes one or more sensors 120. Particularly, for this embodiment, the gas turbine engine 110 includes a plurality of sensors, including a first sensor 120A, a second sensor 120B, a third sensor 120C, and so on to an Nth sensor 120N. The gas turbine engine 110 can include any suitable number of sensors. The sensors 120 can be positioned in any suitable location on the gas turbine engine 110 and can each measure or sense values for various parameters. For example, the first sensor 120A can be a temperature sensor configured to sense the temperature at a station along the hot gas path, e.g., between the HP turbine and LP turbine. The second sensor 120B can be a pressure sensor configured to sense a pressure of the pressurized air discharged from the HP compressor. The third sensor 120C can be a vibration sensor operable to measure the vibration associated with a shaft of the gas turbine engine 110.

The gas turbine engine 110 includes a controller 140. The controller 140 can be an Electronic Engine Controller (EEC) that is a component of a Full Authority Digital Engine Control (FADEC) system, for example. The controller 140 can include one or more processors 142 and one or more memory devices 144. The one or more memory devices 144 can store information, such as instructions and data. The instructions can include executable FADEC logic 146. The FADEC logic 146 can be accessed and executed by the one or more processors. For this embodiment, the FADEC logic 146 includes a damper health component 148. When the one or more processors execute the damper health component 148 of the FADEC logic 146, the controller 140 can monitor a condition or health state of a damper of the gas turbine engine 110.

Particularly, as shown in FIG. 3, the controller 140 receives data 130 from the one or more sensors 120. The data 130 provided to the controller 140 can include sensed values for various parameters. In some embodiments, the sensed values provided in the data 130 can be used to calculate values for other parameters, such as exhaust gas temperature (EGT), efficiencies of the gas turbine engine 110, rotor modes, stall margin, etc. Accordingly, the one or more processors 142 are configured to calculate values for one or more calculated parameters. In some embodiments, the controller 140 can also receive vehicle data 138. The vehicle data 138 can include sensed and/or calculated values associated with vehicle to which the gas turbine engine 110 is mounted. For instance, in embodiments where the vehicle to which the gas turbine engine 110 is mounted is an aerial vehicle, the vehicle data 138 can include, without limitation, sensed and/or calculated parameter values associated with the aerial vehicle such as flight phase, inertial position, ground speed, inertial heading, thrust, drag, lift, weight, horizontal wind speed, wind direction, static pressure and temperature, flight intent parameters, etc.

Upon execution of the damper health component 148 of the FADEC logic 146 by the one or more processors 142, at damper severity index generator block 152, the one or more processors 142 can generate a damper severity index 150 based at least in part on the data 130 received from the one or more sensors 120. The damper severity index 150 indicates a health state of a damper of the gas turbine engine 110. Accordingly, the damper severity index 150 can be used to monitor the health state of the damper.

The damper severity index 150 can be generated using parameter values that are derived from the data 130 received from the one or more sensors 120. The parameter values derived from the data 130 can include sensed parameter values sensed by the one or more sensors 120 and/or calculated parameter values calculated based at least in part on the sensed parameter values sensed by the one or more sensors 120. Notably, the damper severity index 150 can be generated using parameter values for a wide range of parameters associated with the gas turbine engine 110, including without limitation, parameters associated with bowed rotor starts; parameters associated with Non-Synchronous Vibration (NSV) of one or more rotary components of the gas turbine engine 110 (e.g., the shaft to which the bearing associated with the damper is coupled); parameters associated with mode tracking and the response of rotary components in one or more operating ranges of the gas turbine engine 110; parameters associated with oil flow, temperature, and pressure; parameter associated with bearing element pass frequency; parameters associated with rotor-stator clearances for various modes of operation; parameters associated with vibration, velocity, strain, and force on various components of the gas turbine engine 110; parameter associated with the pressure and temperature fluctuation at a particular station along the core air flowpath of the gas turbine engine 110; parameters associated with rotor torque; and other operating parameters, such as the rotor speed of the LP shaft, the rotor speed of the HP shaft, and other temperatures and pressures.

Further, in some embodiments, upon execution of the damper health component 148 of the FADEC logic 146 by the one or more processors 142, at damper severity index generator block 152, the one or more processors 142 can generate the damper severity index 150 based at least in part on the data 130 received from the one or more sensors 120 and based at least in part on the vehicle data 138 received from the vehicle to which the gas turbine engine 110 is mounted. The vehicle data 138 can include sensed and/or calculated parameter values.

In some example embodiments, the damper severity index 150 is generated or calculated as a statistical combination of a collection of parameters, such as a weighted average of a collection of parameters. For instance, as shown in FIG. 3, each parameter can have an associated weight. Specifically, a first parameter P1 has an associated first weight w1, a second parameter P2 has an associated second weight w2, a third parameter P3 has an associated third weight w3, and so on such that an Nth parameter has an associated Nth weight. The weights can indicate a relative importance of a given parameter in calculating the damper severity index 150. The weights can be applied to their respective sensed and/or calculated parameter values and the resultant weighted values can be averaged to determine the damper severity index 150. The assigned weights can be any suitable value, including a weight having a value of one (1) such that the parameter value is not given any weight and a weight having a value of zero (0) such that the parameter value is not considered in the damper severity index 150 calculation.

In some embodiments, the damper severity index 150 is generated or calculated by the one or more processors 142 by executing or applying one or more statistical or machine-learned models 180 as shown in FIG. 3. The one or more memory devices 144 can store the one or more statistical or machine-learned models 180 and the one or more processors 142 can access and apply them. In some embodiments, the one or more statistical or machine-learned models 180 can be one or more classification machine-learned models, such as a decision tree model, a support vector machines model, a Recurrent Neural Network (RNN) with an attention layer, a random forest model, other ensemble models, etc. However, generally, the machine-learned models 180 can use any suitable machine learning technique to generate the damper severity index 150, including a machine and/or statistical learning model structured as one of a Bayesian graph model, a linear discriminant analysis model, a partial least squares discriminant analysis model, a support vector machine model, a random tree model, a regression model, a naïve Bayes model, a K-nearest neighbor model, a quadratic discriminant analysis model, an anomaly detection model, a boosted and bagged decision tree model, an artificial neural network model, a C4.5 model, a k-means model, or a combination of one or more of the foregoing. Other suitable types of machine or statistical learning models are also contemplated. It will also be appreciated that the machine-learned models 180 can use certain mathematical methods alone or in combination with one or more machine or statistical learning models to generate the damper severity index 150, or more generally, an output indicating a health state of a damper of a gas turbine engine.

The one or more machine-learned models 180 can be constructed using any suitable technique. For instance, one or more machine learning algorithms can be used to build or construct the one or more machine-learned models 180 so that the machine-learned models 180 can make predictions or decisions without being explicitly programmed to do so. For instance, the one or more statistical and/or machine learned models 180 can be constructed or trained using a suitable directed, supervised, unsupervised, and/or reinforcement learning technique, or some combination of the foregoing. In this regard, the constructed one or more machine-learned models 180 can be supervised models, unsupervised models, and/or semi-supervised models.

As one example, the one or more machine-learned models 180 can be trained in the following example manner. To train the machine-learned models 180 to accurately output an indicator of a health state of a damper, one or more processors of a computing system can receive or otherwise obtain training data, such as field data from gas turbine engines of a fleet. Each of the gas turbine engines can include a damper, such as squeeze film damper associated with a bearing. The training data can include parameter values for various parameters. The parameter values can indicate the operating conditions present during operation of a given gas turbine engine of the fleet. From the field data, one or more condition indicators can be identified or extracted. In some embodiments, one or more machine learning algorithms can be used to identify the condition indicators from the field data. The condition indicators each indicate a feature or parameter that affects degradation of a damper associated with the one or more gas turbine engines of the fleet. The one or more machine-learned models 180 can then be trained using the one or more condition indicators identified in the field data. The one or more trained machine-learned models 180 can thus be configured to generate an output indicating a health state of a damper of a gas turbine engine upon a new or second set of data being input therein, the second set of field data including parameter values for parameters associated with a gas turbine engine having a damper. In this regard, the one or more machine-learned models 180 can intelligently and accurately predict the health state of the damper of the gas turbine engine.

Particularly, the one or more statistical or machine-learned models 180 can be trained in such a way that they apply weights to the parameter values input therein. The weights can be machine-learned weights that can indicate a relative importance of a given feature or parameter in calculating the damper severity index 150. As will be explained in further detail herein, the one or more classification machine-learned models 180 can be updated and/or retrained periodically by update data 136 provided by a computing system 200. The update data 136 can include updated FADEC logic and/or updated models that can be used to update the FADEC logic 146, and specifically the damper health component 148 of the FADEC logic 146, and/or the one or more statistical or machine-learned models 180. As one example, the update data 136 can include updated weights to be assigned to some or all of the parameters used to generate the damper severity index 150. In addition, the update data 136 can include data that can be used to update the threshold of logic block 154.

Further, upon execution of the damper health component 148 of the FADEC logic 146 by the one or more processors 142, at logic block 154, the one or more processors 142 can determine whether the damper severity index 150 exceeds a threshold. The threshold can be generated using historical field data, for example. The threshold can also be updated in accordance with received update data 136 as noted above. The damper severity index 150 can be a calculated value (e.g., a weighted average) and the threshold can likewise be a value. The value associated with the damper severity index 150 can be compared to the value associated with the threshold to determine whether the damper severity index 150 exceeds the threshold.

When the damper severity index 150 does not exceed the threshold as determined at block 154, the one or more processors 142 can cause field data 132 to be stored in the one or more memory devices 144. The field data 132 can include the calculated damper severity index 150, the parameter values and weights used to calculate the damper severity index 150, and other information. The damper severity index 150 and parameter values and weights used to calculate the damper severity index 150 can be stored as field data 132 each time a damper severity index is generated. In this way, the generated damper severity index 150 can be plotted on a graph depicting the damper severity index as a function of time, for example.

When the damper severity index 150 exceeds the threshold as determined at block 154, the one or more processors 142 can determine that the health state of the damper has degraded to an unacceptable or unsatisfactory state, and accordingly, the one or more processors 142 can proceed with notifying one or more entities regarding the health state of the damper. Specifically, at notification generator block 158, the one or more processors 142 can generate, when the damper severity index 150 exceeds the threshold, a notification 160 indicating the damper severity index 150 exceeds the threshold. Accordingly, the generated notification 160 can indicate the health state of the damper. In some embodiments, optionally, the field data 132, which can include past generated damper severity indices, can be used to generate the notification 160. In this manner, the notification 160 can include past generated damper severity indices, and accordingly, the notification 160 can show the present damper severity index 150 relative to the past generated damper severity indices. In this way, the notification 160 can indicate the trend of the health state of the damper.

Optionally, when the damper severity index 150 exceeds the threshold as determined at block 154, at severity generator block 156, the one or more processors 142 can determine a severity of the health state of the damper based at least in part on the damper severity index 150, and more particularly, based at least in part on the degree the damper severity index 150 deviates from the threshold. For instance, the more the damper severity index 150 deviates from the threshold, the more severe or unacceptable the health of the damper. In contrast, the less the damper severity index 150 deviates from the threshold, the less severe or unacceptable the health of the damper. A sliding scale scoring system can be utilized, for example. For instance, a severity score can be assigned to the damper based at least in part on the deviation between the generated damper severity index 150 and the threshold. The severity of the health state of the damper can be routed to the notification generator block 158 such that the generated notification 160 can include the severity of the health state of the damper, e.g., its severity score.

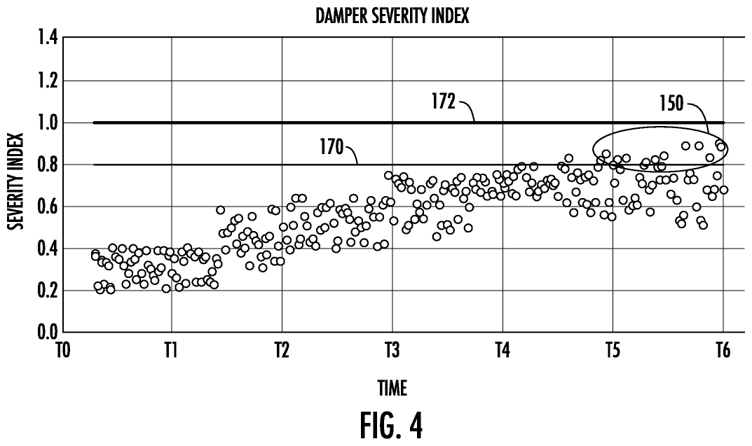

Furthermore, in some embodiments, field data 132 can be provided to the severity generator block 156. The field data 132, which can include past generated damper severity indices, can be used to determine the severity of the health state of the damper. For instance, with reference now to FIGS. 3 and 4, FIG. 4 provides a graph depicting generated damper severity indices plotted as a function of time. When the present damper severity index 150 exceeds the threshold 170 as determined at block 154, in some embodiments, the severity generator 156 can determine whether a predetermined number of generated damper severity indices have exceeded the threshold 170 within a predetermined interval of time.

For instance, as shown in FIG. 4, for the time interval spanning from time T5 to time T6, a predetermined number of generated damper severity indices have exceeded the threshold 170, and thus, the damper is assigned a health state in accordance with this determination and this determination can be included in the notification 160 generated at notification generator block 158. Such a determination may indicate that the damper has degraded beyond an acceptable level and that immediate corrective action (e.g., replacement of the damper) is required. When it is determined that a predetermined number of generated damper severity indices have not exceeded the threshold 170 for a given time interval even though at least one damper severity index has exceeded the threshold 170, e.g., an interval spanning between time T4 and T5, then the damper is assigned a health state in accordance with this determination and this determination can be included in the notification 160 generated at notification generator block 158. Such a determination may indicate that the damper has degraded to a level or state to which corrective action (e.g., replacement of the damper) is required in the near future. Accordingly, a service visit can be scheduled in response to such a notification 160. Furthermore, in some embodiments, the damper severity index 150 can be compared to a critical threshold 172. If the damper severity index 150 has exceeded the critical threshold 172, the notification 160 can include the high importance of the notification 160 and can indicate that the gas turbine engine 110 should not be operated until corrective action has been taken.

The generated notification 160 can be stored in the one or more memory devices 144 and/or output from the controller 140. For instance, the notification 160 can be routed to a communication unit positioned onboard an aerial vehicle to which the gas turbine engine 110 is mounted. The communication unit can then transmit the notification 160 to one or more entities, such as aircraft and/or engine service entities. In addition, the notification 160 can be stored in the memory devices 144, e.g., so that the notification 160 can be accessed at a later time.

As further shown in FIG. 3, the system 100 includes a computing system 200. The computing system 200 can be a remote computing system located remote from the controller 140. For instance, the computing system 200 can be located on the ground, onboard the aircraft to which the gas turbine engine 110 is mounted but spaced from the controller 140, onboard another vehicle, or in any other suitable location. Generally, the computing system 200 is operatively configured to receive data associated with the gas turbine engine 110 as well as data associated with other gas turbine engines of a fleet of which the gas turbine engine 110 is a part, and based on the received data, the computing system is operatively configured to perform data trending, render residual life predictions, perform fault identification and proactive workscoping tasks, and identify parameters that impact damper health more than others, and in doing so, generate updated FADEC control logic based on the identified parameters. For instance, the updated FADEC control logic can include updated weights to be applied to such identified parameters in generating the damper severity index.

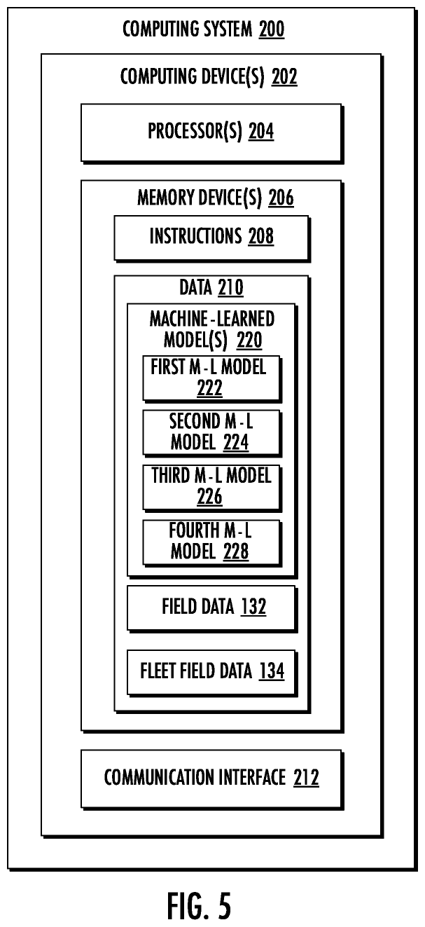

With reference now to FIGS. 3 and 5, FIG. 5 provides a block diagram of the computing system 200 of the system 100 of FIG. 3. The computing system 200 can include one or more processors 204 and one or more memory devices 206. The one or more processors 204 and one or more memory devices can be embodied in one or more computing devices 202. The one or more processors 204 can include or be any suitable processing device, such as a microprocessor, microcontroller, integrated circuit, logic device, or other suitable processing device. The one or more memory devices 206 can include one or more computer-readable medium, including, but not limited to, non-transitory computer-readable medium or media, RAM, ROM, hard drives, flash drives, and other memory devices, such as one or more buffer devices.

The one or more memory devices 206 can store information accessible by the one or more processors 204, including computer-readable instructions 208 that can be executed by the one or more processors 204. The instructions 208 can be any set of instructions that, when executed by the one or more processors, cause the one or more processors 204 to perform operations. The instructions 208 can be software written in any suitable programming language or can be implemented in hardware. The memory devices 206 can further store data 210 that can be accessed by the processors 204. For example, the data 210 can include received field data 132, received fleet field data 134, etc. The data 210 can include one or more table(s), function(s), algorithm(s), model(s), equation(s), etc. according to example embodiments of the present disclosure.

In addition, in some embodiments, the data 210 can include information associated with an engine before and after shipping. As one example, the data 210 can include information associated with the vibration levels of the engine after engine assembly but before the engine is shipped and information associated with the vibration levels of the engine after the engine has been shipped, e.g., to an airframer. The difference in the vibration levels before and after shipping can be calculated for the engine as well as for other engines of the fleet. These calculated differences can be used to identify faults types associated with a damper, among other uses. For instance, if two engines of the same family have accumulated a similar number of cycles and have different damper severity indices, the calculated differences associated with the engines of the family can be used for fault identification. Moreover, such differences can be used to train and/or be used for inputs to one or more of the machine-learned models noted below.

Notably, the data 210 can include one or more machine-learned models 220. In some embodiments, the one or more machine-learned models 220 can be classification models, such as a decision tree model, a support vector machines model, an RNN with an attention layer, a random forest model, other ensemble models, etc. The one or more machine-learned models 220 can be trained using field data 132, fleet field data 134, and/or other training data, such as condition indicators as will be explained further herein. The one or more machine-learned models 220 can be retrained when new field data 132 and/or fleet field data 134 is received.

The machine-learned models 220 can include a first machine-learned model 222, a second machine-learned model 224, a third machine-learned model 226, a fourth machine-learned model 228, as well as others. In some embodiments, the first machine-learned model 222 can be utilized to predict the remaining useful life of a damper. In some embodiments, the second machine-learned model 224 can be utilized to identify fault types associated with the damper, which can provide insight into the root cause for damper degradation. The known damper fault type can be used for workscoping purposes, e.g., to schedule maintenance for a particular component of the engine. In some embodiments, the third machine-learned model 226 can be utilized to detect anomalies in the received field data. Detection of such anomalies can be useful for many reasons. Further, the fourth machine-learned model 228 can be utilized to identify parameters that impact the health state of a damper.

The fourth machine-learned model 228 can be used to classify the parameters. For instance, the fourth machine-learned model 228 can be used to classify the parameters by the degree in which a parameter affects degradation of a damper, e.g., relative to the other parameters. In this manner, the fourth machine-learned model 228 can rank the parameters or determined classes based at least in part on the impact the parameter has on the degradation of the damper. Notably, the controllers associated with their respective engines of the fleet can be updated with FADEC logic that includes new or updated weights that can be assigned to their respective parameters. The weights can be updated based at least in part on the class or rank of their associated parameters as determined by the fourth machine-learned model 228. The new or updated weights can be used to generate future damper severity indices. In this manner, the accuracy of the damper severity indices generated by the controller can become more accurate over time, which improves the overall monitoring of the damper or dampers of a gas turbine engine.

The computing system 200 can also include a communication interface 212 used to communicate, for example, with other components of the system 100 or other systems or devices. The communication interface 212 can include any suitable components for interfacing with one or more network(s), including for example, transmitters, receivers, ports, controllers, antennas, or other suitable components. In addition, in some embodiments, the communication interface 212 can be used to alert engine operating entities, such as airliners, of the remaining useful life of a damper and/or other information associated with the damper. As one example, if a fault has been identified from the field data 132, but the damper severity index 150 is still below the threshold, the damper may start to deteriorate faster than predicted. In such a case, a new Remaining Useful Life (RUL) of the damper can be communicated to the engine operating entity along with the fault type.

With reference to FIGS. 3 and 5, the one or more processors 204 of the computing system 200 can receive, from one or more gas turbine engines of a fleet, field data. That is, the computing system 200 can receive field data from one, some, or all the gas turbine engines of a fleet. In this manner, the computing system 200 can receive fleet field data 134, which can include field data 132 associated with the gas turbine engine 110. The field data received from a given one of the gas turbine engines of the fleet can include parameter values for parameters associated with the given gas turbine engine. The field data received from the gas turbine engines of the fleet can also include calculated damper severity indices, the parameter values and weights used to calculate the damper severity index, and other information. The field data can also include the generated notification 160 and/or past notifications stored in the one or more memory devices 144 of the controller 140. Each of the gas turbine engines that provide their respective field data can each include a damper, such as a squeeze film damper associated with a bearing operatively coupling a rotary component. The fleet can be made up of similar engines generally, engines that are mounted to a particular aircraft, or engines all being the same engine model, for example.

In some embodiments, the collected field data, which can include field data 132 and/or fleet field data 134, can represent healthy and faulty operation under varying operating conditions of their respective gas turbine engines. A mathematical model for a given damper can be built. The model can be implemented by the one or more processors 204 to estimate or forecast parameter values. The model can then be simulated with different fault states under varying operating conditions to generate fault data or damper fault signatures. The data output by the model, also referred to as synthetic data, can be used to supplement actual sensor data. A combination of synthetic and sensor data can be used to develop a predictive maintenance model.

With the data collected, which can include actual sensor data from field data 132 and/or fleet field data 134 as well as synthetic data, the one or more processors 204 of the computing system 200 can process the data. For instance, the data can be converted into a form from which condition indicators can be easily extracted. One or more preprocessing techniques can be used to remove noise, outliers, and missing values, for example. Further, in some embodiments, one or more preprocessing techniques can be used to reveal additional information that may not be apparent in the original form of the data. For example, preprocessing the data can include converting time-domain data to frequency-domain data.

The one or more processors 204 of the computing system 200 can identify or extract one or more condition indicators from the field data. The one or more condition indicators can each indicate a feature identified from the field data that affects degradation of a damper associated with the engines of the fleet. In some embodiments, the one or more identified condition indicators can be features that each change in a predictable way as the damper degrades. Such features or parameters can be used to discriminate between healthy and faulty damper operation, for example.

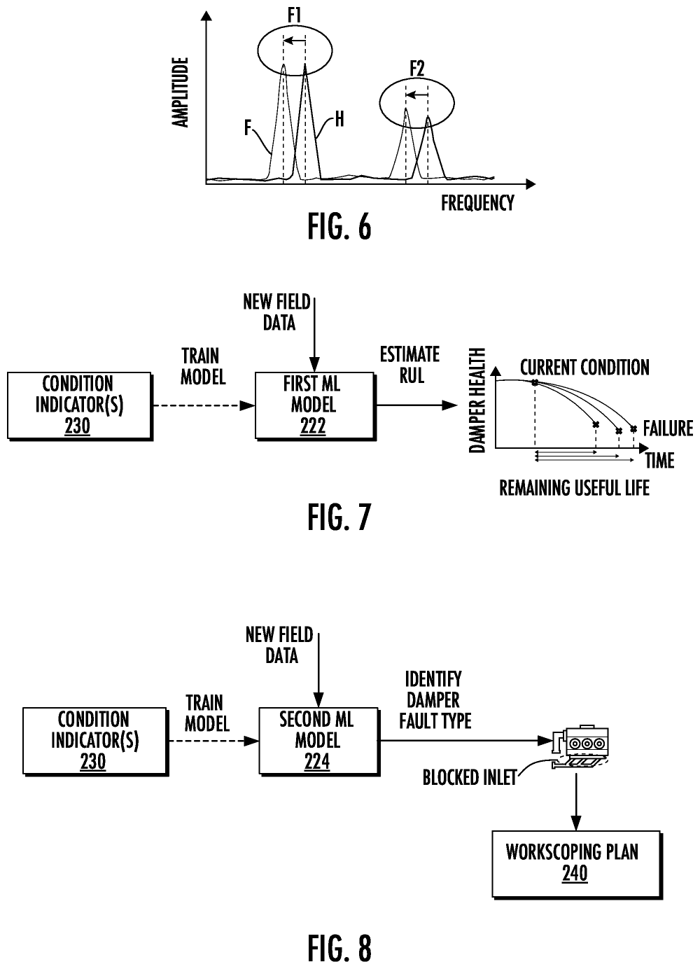

As one example, FIG. 6 provides a graph depicting the amplitude of a healthy signal H for a parameter as a function of frequency during healthy operation of the damper. Further, FIG. 6 also depicts the amplitude of a faulty operation signal F for the parameter as a function of frequency during faulty operation of the damper. As shown, the peaks in the faulty operation signal F shift left or occur at lower frequencies than does the healthy operation signal H. Particularly, the first peak of the faulty operation signal F shifts left with respect to the first peak of the healthy operation signal by a frequency of F1. Similarly, the second peak of the faulty operation signal F shifts left with respect to the second peak of the healthy operation signal by a frequency of F2. Notably, the further the damper degrades, the further the faulty operation signal F shifts left at the peaks with respect to corresponding peaks of the healthy signal H. The peak frequencies and their correlation can serve as condition indicators. As will be appreciated, the correlation between peak frequencies of a healthy and faulty signal is only one example manner in which a condition indicator can be identified or extracted from the field data. Other suitable correlations or features can be extracted from the field data as well.

With reference now to FIGS. 3, 5, and 7, in some embodiments, the one or more processors 204 of the computing system 200 can train a first model using the one or more identified condition indicators 230 to render the first machine-learned model 222. The condition indicators 230 can be used to adjust the weights or weighed functions applied to inputs of the first machine-learned model 222. The first machine-learned model 222 can be a classification model, such as, without limitation, a decision tree model, a support vector machines model, an RNN with an attention layer, a random forest model, other ensemble models, etc. With the first machine-learned model 222 trained, the one or more processors 204 of the computing system 200 can receive, from a gas turbine engine of the fleet, a new or second set of field data. The new or second set of field data can include parameter values for parameters associated with the gas turbine engine. The parameter values can be derived from engine sensors and/or vehicle data and can be sensed and/or calculated values. The one or more processors 204 of the computing system 200 can generate, using the second set of field data as an input to the first machine-learned model 222, an output indicating a remaining useful life of the damper of the gas turbine engine.

With reference now to FIGS. 3, 5, and 8, in yet other embodiments, the one or more processors 204 of the computing system 200 can train a second model using the one or more identified condition indicators 230 to render a second machine-learned model 224. The condition indicators 230 can be used to adjust the weights or weighed functions applied to inputs of the second machine-learned model 224. The second machine-learned model 224 can be a classification model, such as, without limitation, a decision tree model, a support vector machines model, an RNN with an attention layer, a random forest model, other ensemble models, etc. With the second machine-learned model 224 trained, the one or more processors 204 of the computing system 200 can receive, from a gas turbine engine of the fleet, a new or second set of field data. The new or second set of field data can include parameter values for parameters associated with the gas turbine engine. The parameter values can be derived from engine sensors and/or vehicle data and can be sensed and/or calculated values. The one or more processors 204 of the computing system 200 can generate, using the second set of field data as an input to the second machine-learned model 224, an output indicating a fault type of the damper. Further, in some embodiments, the one or more processors 204 of the computing system 200 can generate a workscoping plan 240 based at least in part on the output indicating the fault type of the damper. The workscoping plan 240 can specify one or more components of the damper that require attention, for example.

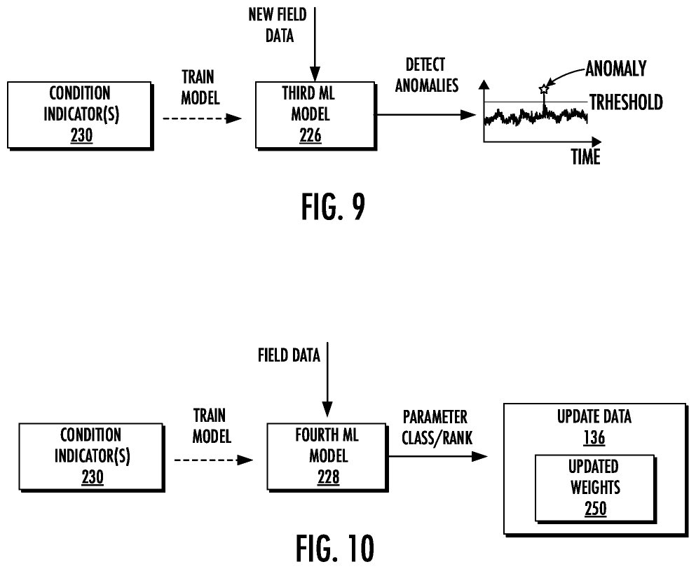

With reference now to FIGS. 3, 5, and 9, in some other embodiments, the one or more processors 204 of the computing system 200 can train a third model using the one or more identified condition indicators 230 to render a third machine-learned model 226. The condition indicators 230 can be used to adjust the weights or weighed functions applied to inputs of the third machine-learned model 226. The third machine-learned model 226 can be a classification model, such as, without limitation, a decision tree model, a support vector machines model, an RNN with an attention layer, a random forest model, other ensemble models, etc. With the third machine-learned model 226 trained, the one or more processors 204 of the computing system 200 can receive, from a gas turbine engine of the fleet, a new or second set of field data. The new or second set of field data can include parameter values for parameters associated with the gas turbine engine. The parameter values can be derived from engine sensors and/or vehicle data and can be sensed and/or calculated values. The one or more processors 204 of the computing system 200 can generate, using the second set of field data as an input to the third machine-learned model 226, an output indicating an anomaly in the field data.

With reference now to FIGS. 3, 5, and 10, in some embodiments, the computing system 200, using the fourth machine-learned model 228, can determine or identify parameters that impact or affect damper health. The fourth machine-learned model 228 can be any suitable type of machine-learned model. For instance, the fourth machine-learned model 228 can be a suitable classification model, such as, without limitation, a decision tree model, a support vector machines model, an RNN with an attention layer, a random forest model, other ensemble models, etc. The fourth machine-learned model 228 can be trained using identified condition indicators 230 as well as historical field data, for example.

In some embodiments, the computing system 200, using the fourth machine-learned model 228, can classify parameters by a degree in which a parameter affects degradation of a damper, e.g., relative to the other parameters. With the parameters classified, the fourth machine-learned model 228 can rank the parameters or determined classes based on the impact the parameter has on the degradation of the damper. Accordingly, update data 136 can be generated by the computing system 200. The update data 136 can include updated weights 250. The updated weights 250 can be updated based at least in part on the class or rank of their associated parameters as determined by the fourth machine-learned model 228.

The update data 136 that includes the updated weights 250 can be provided to the controller 140 of the gas turbine engine 110. The updated weights 250 can replace, update, or otherwise supplement the present weights of the FADEC logic 146 to be applied to the parameters during generation of the damper severity index 150. This update process can be performed periodically. In this way, the computing system 200 can generate and provide a self-evolving damper PHM logic to the controller 140 of the gas turbine engine 110. In this manner, the accuracy of the damper severity indices generated by the controller 140 can become more accurate over time, which improves the overall monitoring of the damper or dampers of a gas turbine engine. Moreover, the update data 136 can be provided to all engines in a fleet.

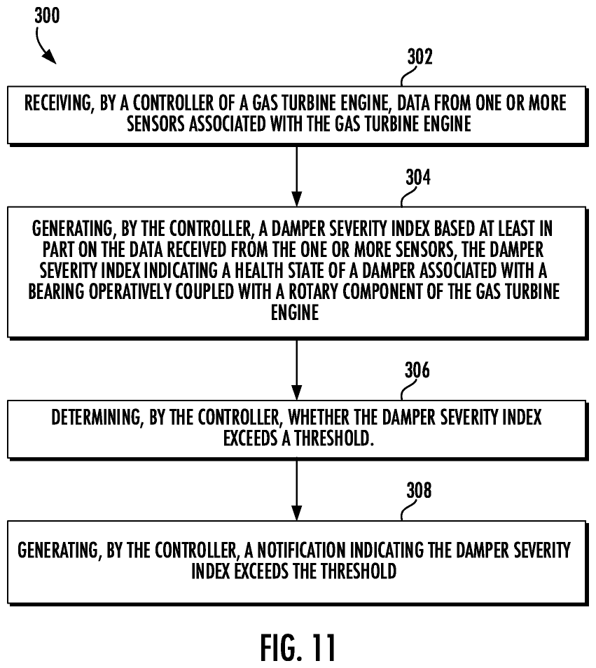

FIG. 11 provides a flow diagram for a method (300) of monitoring a health state of a damper of a gas turbine engine according to an example embodiment of the present disclosure. FIG. 11 can be implemented by one or more components of the system 100 described herein. One or more step(s) of the method (300) can be performed while the aircraft to which the gas turbine engine is mounted is in-flight. In addition, FIG. 11 depicts steps performed in a particular order for purposes of illustration and discussion. Those of ordinary skill in the art, using the disclosures provided herein, will understand that the various steps of any of the methods disclosed herein can be modified, adapted, expanded, rearranged and/or omitted in various ways without deviating from the scope of the present disclosure.

At (302), the method (300) includes receiving, by a controller of a gas turbine engine, data from one or more sensors associated with the gas turbine engine. For instance, the controller can be the controller 140 and the gas turbine engine can be the gas turbine engine 110 depicted in FIG. 3. The gas turbine engine can include a damper associated with a bearing operatively coupled with a rotary component. The data from the one or more sensors can include parameter values for one or parameters. The parameter values can be derived from engine sensors and/or vehicle data and can be sensed and/or calculated values.

In some implementations, the parameters can include at least one parameter associated with a bowed rotor start of the rotary component, at least one parameter associated with non-synchronous vibration of the rotary component, at least one parameter associated with mode tracking and the response of the rotary component in one or more operating ranges of the gas turbine engine, and/or at least one parameter associated with oil flow, temperature, or pressure. In addition, in some implementations, the parameters can include at least one parameter associated with rotor-stator clearances for various modes of operation; at least one parameter associated with vibration, velocity, strain, and force on various components of the gas turbine engine; at least one parameter associated with the pressure and temperature fluctuation at a particular station along the core air flowpath of the gas turbine engine; at least one parameter associated with rotor torque; and/or at least one parameter associated with rotor speed of the LP shaft, the rotor speed of the HP shaft, and other temperatures and pressures associated with the engine.

At (304), the method (300) includes generating, by the controller, a damper severity index based at least in part on the data received from the one or more sensors, the damper severity index indicating a health state of a damper associated with a bearing operatively coupled with a rotary component of the gas turbine engine. In some implementations, the controller generates the damper severity index using one or more statistical or machine-learned models, such as one of the classification models noted herein. In some implementations, the damper severity index is generated using parameter values for parameters, the parameter values being derived from the data received from the one or more sensors. Each of the parameters can have a weight assigned thereto. In such implementations, generating at (304), by the controller, includes applying, by the controller for each of the parameter values, the weight to the parameter value associated with the parameter to which the weight is assigned to render a weighed value. A weighted value can be determined for each parameter. Further, in such implementations, generating at (304) can include determining, by the controller, a weighted average of the weighted values.

At (306), the method (300) includes determining, by the controller, whether the damper severity index exceeds a threshold.

At (308), the method (300) includes generating, by the controller, a notification indicating the damper severity index exceeds the threshold. The notification can indicate that the damper severity index exceeds the threshold. Accordingly, the generated notification can indicate the health state of the damper.

In some further implementations, the method (300) can include receiving, by a computing system from one or more gas turbine engines of a fleet, field data. For instance, the computing system can be the computing system 200 of FIGS. 3 and 5. The field data received from a given one of the one or more gas turbine engines of the fleet can include parameter values for parameters associated with the given one of the one or more gas turbine engines. Each of the one or more gas turbine engines can include a damper, such as a squeeze film damper. That is, each gas turbine engine can include or have a specific damper positioned in a specific location. Further, the method (300) can include identifying, by the computing system, one or more condition indicators from the field data. The one or more condition indicators can each indicate a feature identified from the field data that affects degradation of the damper being considered. The method (300) can also include training, by the computing system, a fourth machine-learned model using the one or more condition indicators. For instance, the fourth machine-learned model can be the fourth machine-learned model 228 of FIGS. 5 and 10.

In addition, the method (300) can include classifying, using a second set of field data received from the gas turbine engine as an input to the fourth machine-learned model, parameters by a degree in which a parameter affects degradation of the damper of the gas turbine engine. Further, the method (300) can include ranking, by the computing system, the parameters based at least in part on the classification of the parameters. In addition, the method (300) can include generating, by the computing system, updated weights to be assigned to the parameters based at least in part on the ranks of the parameters. For instance, as shown in FIG. 10, the updated weights 250 are shown generated. Further, the method (300) can include updating the controller to include the updated weights. For instance, as shown in FIG. 3, the update data 136, which can include the updated weights 250 (FIG. 10), can be provided to the controller 140 of the gas turbine engine 110. As noted above, the updated weights 250 can replace, update, or otherwise supplement the present weights of the FADEC logic 146 to be applied to the parameters during generation of the damper severity index 150. This update process can be performed periodically. In this way, the computing system 200 can generate and provide a self-evolving damper PHM logic to the controller 140 of the gas turbine engine 110.

The technology discussed herein makes reference to computer-based systems and actions taken by and information sent to and from computer-based systems. It will be appreciated that the inherent flexibility of computer-based systems allows for a great variety of possible configurations, combinations, and divisions of tasks and functionality between and among components. For instance, processes discussed herein can be implemented using a single computing device or multiple computing devices working in combination. Databases, memory, instructions, and applications can be implemented on a single system or distributed across multiple systems. Distributed components can operate sequentially or in parallel.

Although specific features of various embodiments may be shown in some drawings and not in others, this is for convenience only. In accordance with the principles of the present disclosure, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

Further aspects of the invention are provided by the subject matter of the following clauses:

1. A gas turbine engine, comprising: a rotary component rotatable about an axis of rotation; a bearing operatively coupled with the rotary component; a damper associated with the bearing; one or more sensors; a controller communicatively coupled with the one or more sensors, the controller having one or more processors and one or more memory devices, the one or more processors of the controller being configured to: receive data from the one or more sensors; generate a damper severity index based at least in part on the data received from the one or more sensors, the damper severity index indicating a health state of the damper; determine whether the damper severity index exceeds a threshold; and generate, when the damper severity index exceeds the threshold, a notification indicating the health state of the damper.

2. The gas turbine engine of any preceding clause, wherein the one or more processors of the controller generate the damper severity index using one or more statistical or machine-learned models.

3. The gas turbine engine of any preceding clause, wherein the one or more processors of the controller are further configured to: determine a severity of the health state of the damper based at least in part on the damper severity index, wherein the severity of the damper is based at least in part on a degree the damper severity index deviates from the threshold.

4. The gas turbine engine of any preceding clause, wherein the damper severity index is generated using parameter values for parameters, the parameter values being derived from the data received from the one or more sensors, the parameters including at least one parameter associated with a bowed rotor start of the rotary component.

5. The gas turbine engine of any preceding clause, wherein the damper severity index is generated using parameter values for parameters, the parameter values being derived from the data received from the one or more sensors, the parameters including at least one parameter associated with non-synchronous vibration of the rotary component.

6. The gas turbine engine of any preceding clause, wherein the damper severity index is generated using parameter values for parameters, the parameter values being derived from the data received from the one or more sensors, the parameters including at least one parameter associated with mode tracking and the response of the rotary component in one or more operating ranges of the gas turbine engine.

7. The gas turbine engine of any preceding clause, wherein the damper severity index is generated using parameter values for parameters, the parameter values being derived from the data received from the one or more sensors, the parameters including at least one parameter associated with oil flow, temperature, or pressure.

8. The gas turbine engine of any preceding clause, wherein the damper severity index is calculated as a weighted average of a plurality of parameter values.

9. The gas turbine engine of any preceding clause, wherein the damper is a squeeze film damper.

10. A method, comprising: receiving, by a controller of a gas turbine engine, data from one or more sensors associated with the gas turbine engine; generating, by the controller, a damper severity index based at least in part on the data received from the one or more sensors, the damper severity index indicating a health state of a damper associated with a bearing operatively coupled with a rotary component of the gas turbine engine; determining, by the controller, whether the damper severity index exceeds a threshold; and generating, by the controller, a notification indicating the damper severity index exceeds the threshold.

11. The method of any preceding clause, wherein the damper severity index is generated using parameter values for parameters, the parameter values being derived from the data received from the one or more sensors, each of the parameters having a weight assigned thereto, and wherein generating, by the controller, the damper severity index comprises: applying, by the controller for each of the parameter values, the weight to the parameter value associated with the parameter to which the weight is assigned to render weighed values, and determining, by the controller, a weighted average of the weighted values or a statistical combination of the weighted values.

12. The method of any preceding clause, wherein the damper severity index is generated using parameter values for parameters, the parameter values being derived from the data received from the one or more sensors, the parameters including at least one parameter associated with a bowed rotor start of the rotary component, at least one parameter associated with non-synchronous vibration of the rotary component, at least one parameter associated with mode tracking and the response of the rotary component in one or more operating ranges of the gas turbine engine, and at least one parameter associated with oil flow, temperature, or pressure.

13. The method of any preceding clause, further comprising: receiving, by a computing system from one or more gas turbine engines of a fleet, field data, the field data received from a given one of the one or more gas turbine engines including parameter values for parameters associated with the given one of the one or more gas turbine engines, each of the one or more gas turbine engines including a damper, the gas turbine engine being one of the one or more gas turbine engines of the fleet; identifying, by the computing system, one or more condition indicators from the field data, the one or more condition indicators each indicating a feature identified from the field data that affects degradation of at least one of the dampers; and training, by the computing system, a fourth machine-learned model using the one or more condition indicators.

14. The method of any preceding clause, further comprising: classifying, using a second set of field data received from the gas turbine engine as an input to the fourth machine-learned model, parameters by a degree in which a parameter affects degradation of the damper of the gas turbine engine; ranking, by the computing system, the parameters based at least in part on the classification of the parameters; and generating, by the computing system, updated weights to be assigned to the parameters based at least in part on the ranks of the parameters.

15. The method of any preceding clause, further comprising: updating the controller to include the updated weights.

16. A non-transitory computer readable medium comprising computer-executable instructions, which, when executed by one or more processors, cause the one or more processors to: access field data received from one or more gas turbine engines of a fleet, the field data received from a given one of the one or more gas turbine engines including parameter values for parameters associated with the given one of the one or more gas turbine engines, each of the one or more gas turbine engines including a damper; access a machine-learned model trained using one or more condition indicators identified from the field data, the one or more condition indicators each indicating a feature identified from the field data related to degradation of at least one of the dampers; receive a second set of field data that includes parameter values for parameters associated with a gas turbine engine having a damper; and generate, using the second set of field data as an input to the machine-learned model, an output indicating a remaining useful life of the damper of the gas turbine engine.

17. The non-transitory computer readable medium of claim 16, wherein in executing the computer-executable instructions, the one or more processors are further caused to: access a second machine-learned model trained using the one or more condition indicators identified from the field data; and generate, using the second set of field data as an input to the second machine-learned model, an output indicating a fault type of the damper.

18. The non-transitory computer readable medium of claim 17, wherein in executing the computer-executable instructions, the one or more processors are further caused to: generate a workscoping plan for the damper based at least in part on the output indicating the fault type of the damper.

19. The non-transitory computer readable medium of claim 16, wherein in executing the computer-executable instructions, the one or more processors are further caused to: access a third machine-learned model trained using the one or more condition indicators identified from the field data; and generate, using the second set of field data as an input to the third machine-learned model, an output indicating an anomaly in the field data.

20. The non-transitory computer readable medium of claim 16, wherein in executing the computer-executable instructions, the one or more processors are further caused to: access a fourth machine-learned model trained using the one or more condition indicators identified from the field data; classify, using the second set of field data as an input to the fourth machine-learned model, parameters by a degree in which a parameter affects degradation of the damper; rank the parameters based at least in part on the classification of the parameters; and generate updated weights to be assigned to the parameters based at least in part on the ranks of the parameters.

21. A method of training a machine-learned model, the method comprising: receiving, by one or more computing devices, field data from one or more gas turbine engines of a fleet, the field data received from a given one of the one or more gas turbine engines including parameter values for parameters associated with the given one of the one or more gas turbine engines, each of the one or more gas turbine engines including a damper; identifying, by the one or more computing devices, one or more condition indicators from the field data that each indicate a parameter that affects degradation of a damper associated with the one or more gas turbine engines of the fleet; and training, by the one or more computing devices, the machine-learned model using the one or more condition indicators identified in the field data, the trained machine-learned model being configured to generate an output indicating a health state of a damper of a gas turbine engine upon a second set of data being input therein, the second set of field data including parameter values for parameters associated with a gas turbine engine having a damper.

What is claimed is:

1. A gas turbine engine, comprising:
a rotary component rotatable about an axis of rotation;
a bearing operatively coupled with the rotary component;
a damper associated with the bearing;
one or more sensors;
a controller communicatively coupled with the one or more sensors, the controller having one or more processors and one or more memory devices, the one or more processors of the controller being configured to:
receive data from the one or more sensors;
generate a damper severity index based at least in part on the data received from the one or more sensors, the damper severity index indicating a health state of the damper;
determine whether the damper severity index exceeds a threshold; and
generate, when the damper severity index exceeds the threshold, a notification indicating the health state of the damper.

2. The gas turbine engine of claim 1, wherein the one or more processors of the controller generate the damper severity index using one or more statistical or machine-learned models.

3. The gas turbine engine of claim 1, wherein the one or more processors of the controller are further configured to:
determine a severity of the health state of the damper based at least in part on the damper severity index, wherein the severity of the damper is based at least in part on a degree the damper severity index deviates from the threshold.

4. The gas turbine engine of claim 1, wherein the damper severity index is generated using parameter values for parameters, the parameter values being derived from the data received from the one or more sensors, the parameters including at least one parameter associated with a bowed rotor start of the rotary component.

5. The gas turbine engine of claim 1, wherein the damper severity index is generated using parameter values for parameters, the parameter values being derived from the data received from the one or more sensors, the parameters including at least one parameter associated with non-synchronous vibration of the rotary component.

6. The gas turbine engine of claim 1, wherein the damper severity index is generated using parameter values for parameters, the parameter values being derived from the data received from the one or more sensors, the parameters including at least one parameter associated with mode tracking and the response of the rotary component in one or more operating ranges of the gas turbine engine.

7. The gas turbine engine of claim 1, wherein the damper severity index is generated using parameter values for parameters, the parameter values being derived from the data received from the one or more sensors, the parameters including at least one parameter associated with oil flow, temperature, or pressure.

8. The gas turbine engine of claim 1, wherein the damper severity index is calculated as a weighted average of a plurality of parameter values.

9. The gas turbine engine of claim 1, wherein the damper is a squeeze film damper.

10. A method, comprising:
receiving, by a controller of a gas turbine engine, data from one or more sensors associated with the gas turbine engine;
generating, by the controller, a damper severity index based at least in part on the data received from the one or more sensors, the damper severity index indicating a health state of a damper associated with a bearing operatively coupled with a rotary component of the gas turbine engine;
determining, by the controller, whether the damper severity index exceeds a threshold; and
generating, by the controller, a notification indicating the damper severity index exceeds the threshold.

11. The method of claim 10, wherein the damper severity index is generated using parameter values for parameters, the parameter values being derived from the data received from the one or more sensors, each of the parameters having a weight assigned thereto, and wherein generating, by the controller, the damper severity index comprises:
applying, by the controller for each of the parameter values, the weight to the parameter value associated with the parameter to which the weight is assigned to render weighed values, and
determining, by the controller, a weighted average of the weighted values or a statistical combination of the weighted values.

12. The method of claim 10, wherein the damper severity index is generated using parameter values for parameters, the parameter values being derived from the data received from the one or more sensors, the parameters including at least one parameter associated with a bowed rotor start of the rotary component, at least one parameter associated with non-synchronous vibration of the rotary component, at least one parameter associated with mode tracking and the response of the rotary component in one or more operating ranges of the gas turbine engine, and at least one parameter associated with oil flow, temperature, or pressure.

13. The method of claim 10, further comprising:
receiving, by a computing system from one or more gas turbine engines of a fleet, field data, the field data received from a given one of the one or more gas turbine engines including parameter values for parameters associated with the given one of the one or more gas turbine engines, each of the one or more gas turbine engines including a damper, the gas turbine engine being one of the one or more gas turbine engines of the fleet;
identifying, by the computing system, one or more condition indicators from the field data, the one or more condition indicators each indicating a feature identified from the field data that affects degradation of at least one of the dampers; and
training, by the computing system, a fourth machine-learned model using the one or more condition indicators.

14. The method of claim 13, further comprising:
classifying, using a second set of field data received from the gas turbine engine as an input to the fourth machine-learned model, parameters by a degree in which a parameter affects degradation of the damper of the gas turbine engine;
ranking, by the computing system, the parameters based at least in part on the classification of the parameters; and
generating, by the computing system, updated weights to be assigned to the parameters based at least in part on the ranks of the parameters.

15. The method of claim 14, further comprising:
updating the controller to include the updated weights.

16. A non-transitory computer readable medium comprising computer-executable instructions, which, when executed by one or more processors, cause the one or more processors to:
access field data received from one or more gas turbine engines of a fleet, the field data received from a given one of the one or more gas turbine engines including parameter values for parameters associated with the given one of the one or more gas turbine engines, each of the one or more gas turbine engines including a damper;
access a machine-learned model trained using one or more condition indicators identified from the field data, the one or more condition indicators each indicating a feature identified from the field data related to degradation of at least one of the dampers;
receive a second set of field data that includes parameter values for parameters associated with a gas turbine engine having a damper; and
generate, using the second set of field data as an input to the machine-learned model, an output indicating a remaining useful life of the damper of the gas turbine engine.

17. The non-transitory computer readable medium of claim 16, wherein in executing the computer-executable instructions, the one or more processors are further caused to:
access a second machine-learned model trained using the one or more condition indicators identified from the field data; and
generate, using the second set of field data as an input to the second machine-learned model, an output indicating a fault type of the damper.

18. The non-transitory computer readable medium of claim 17, wherein in executing the computer-executable instructions, the one or more processors are further caused to:
generate a workscoping plan for the damper based at least in part on the output indicating the fault type of the damper.

19. The non-transitory computer readable medium of claim 16, wherein in executing the computer-executable instructions, the one or more processors are further caused to:
access a third machine-learned model trained using the one or more condition indicators identified from the field data; and
generate, using the second set of field data as an input to the third machine-learned model, an output indicating an anomaly in the field data.

20. The non-transitory computer readable medium of claim 16, wherein in executing the computer-executable instructions, the one or more processors are further caused to:
access a fourth machine-learned model trained using the one or more condition indicators identified from the field data;
classify, using the second set of field data as an input to the fourth machine-learned model, parameters by a degree in which a parameter affects degradation of the damper;
rank the parameters based at least in part on the classification of the parameters; and
generate updated weights to be assigned to the parameters based at least in part on the ranks of the parameters.

21. A method of training a machine-learned model, the method comprising:
receiving, by one or more computing devices, field data from one or more gas turbine engines of a fleet, the field data received from a given one of the one or more gas turbine engines including parameter values for parameters associated with the given one of the one or more gas turbine engines, each of the one or more gas turbine engines including a damper;
identifying, by the one or more computing devices, one or more condition indicators from the field data that each indicate a parameter that affects degradation of a damper associated with the one or more gas turbine engines of the fleet; and
training, by the one or more computing devices, the machine-learned model using the one or more condition indicators identified in the field data, the trained machine-learned model being configured to generate an output indicating a health state of a damper of a gas turbine engine upon a second set of data being input therein, the second set of field data including parameter values for parameters associated with a gas turbine engine having a damper.
